(19) United States
(12) Patent Application Publication
(10) Pub. No.: US 2023/0407474 A1
(43) Pub. Date: Dec. 21, 2023

(54) AN ATOMIC LAYER DEPOSITION APPARATUS AND A METHOD

(71) Applicant: BENEQ OY, Espoo (FI)

(72) Inventors: Mika JAUHIAINEN, Espoo (FI); Pekka SOININEN, Espoo (FI)

(21) Appl. No.: 18/248,455

(22) PCT Filed: Oct. 11, 2021
(86) PCT No.: PCT/FI2021/050673

§ 371 Date: Apr. 10, 2023

(30) Foreign Application Priority Data
Oct. 12, 2020 (FI) 20206001

(51) Int. Cl. C23C 16/455; C23C 16/458

(52) U.S. Cl. CPC C23C 16/45551; C23C 16/45527; C23C 16/4588

(57) ABSTRACT

An atomic layer deposition apparatus and a method for processing a surface of a substrate successively with at least a first precursor and a second precursor. The apparatus includes a substrate support and a precursor supply head. The substrate support and the precursor supply head are arranged opposite to each other such that a reaction gap is provided between the substrate support and the precursor supply head. The apparatus further includes a moving mechanism arranged to rotate the substrate support and the precursor supply head relative to each other. The moving mechanism is arranged move the substrate support and the precursor supply head relative to each other in a moving direction such that the reaction gap is adjusted.

### FIELD OF THE INVENTION

The present invention relates to an atomic layer deposition apparatus and more particularly to an atomic layer deposition apparatus according to preamble of claim 1. The present invention further relates to a method for operating an atomic layer deposition apparatus and more particularly to a method according to preamble of claim 10.

### BACKGROUND OF THE INVENTION

Manufacturing or coating substrates and especially planar substrates such as semiconductor wafers, with atomic layer deposition high throughput and high quality of formed thin films are important. However, in prior art devices the high throughput, or processing speed, of the apparatus and high coating quality are often contradictory relative each other. This means that increasing the throughput of the apparatus the coating quality is compromised. On the other hand, achieving high coating quality requires lowering the throughput of the apparatus.

Prior art atomic layer deposition apparatuses comprise solution in which a rotating substrate support is used. One or more substrates are supported on a support surface of the substrate surface. A precursor supply head is positioned opposite the substrate support such that an output face of the precursor supply head is arranged opposite and parallel to the support surface of the substrate support. A reaction gap is provided between the support surface and the output face. Precursor material or materials are supplied via the output face towards the support surface to which the one or more substrates are supported for subjecting the surface of the substrate to precursors. The output face comprises one or more reaction zones or precursor nozzles via which the precursors are supplied towards the support surface and the substrate. The substrate support is rotated around a rotating axis which is perpendicular to the support surface. When the substrate support is rotated, the one or more substrates move successively and repeatedly under the one or more reaction zone or precursor nozzles thus subjecting the surface if the substrate to precursors. The apparatus further comprises a vacuum chamber or reaction chamber surrounding the substrate support, or the substrate support and the precursor supply head. The vacuum chamber is connected to a suction device which is arranged to provide vacuum inside the vacuum chamber such that the substrates are protected from contamination from ambient atmosphere and such that precursor gases do not escape to the ambient atmosphere.

The one or more through holes extend between the support surface and the back surface of the substrate support. The one or more through holes are open to the support surface and to the reaction gap between the support surface and the output face. The one or more through holes are open to a chamber space defined by the a vacuum chamber or reaction chamber.

In the apparatuses disclosed above, the substrates are processed in the reaction gap height of which is normally only couple of mm. In the prior art apparatuses, loading and unloading of substrates is carried out by breaking the vacuum atmosphere in the vacuum chamber and opening a vacuum chamber door and letting the apparatus to cool down. Then, the precursor supply head removed and the substrates are unloaded and new substrates loaded by hand. This is time consuming and slow operation and further the apparatus and substrates are subjected to contamination and moisture from ambient atmosphere. Thus, both the throughput and quality are compromised.

### BRIEF DESCRIPTION OF THE INVENTION

An object of the present invention is to provide an atomic layer deposition apparatus and method for operating an atomic layer deposition apparatus such that prior art disadvantages are solved or at least alleviated.

The objects of the invention are achieved by an atomic layer deposition apparatus which is characterized by what is stated in the independent claim 1. The objects of the invention are also achieved by a method which is characterized by what is stated in the independent claim 10.

The preferred embodiments of the invention are disclosed in the dependent claims.

The invention is based on the idea of providing an atomic layer deposition apparatus for processing a surface of a substrate successively with at least a first precursor and a second precursor. The apparatus comprises a substrate support having a support surface and arranged to support one or more substrates, and a precursor supply head having an output face via which precursors are supplied. The support surface of the substrate support and the output face of the precursor supply head are arranged opposite to each other such that a reaction gap is provided between the support surface of the substrate support and the output face of the precursor supply head. The apparatus further comprises a moving mechanism, the substrate support and the precursor supply head are arranged to be rotated relative to each other with the moving mechanism such that the support surface of the substrate support and the output face of the precursor supply head are arranged to be rotated relative to each other.

According to the present invention, the moving mechanism is further arranged to move the substrate support and the precursor supply head relative to each other in a moving direction extending between the support surface of the substrate support and the output face of the precursor supply head such that the reaction gap is adjusted.

Thus, height of the reaction gap may be adjusted by moving the substrate support and the precursor supply head relative to each other. This allows utilizing a reaction gap which is suitable for different coating processes. Thus, different reaction gaps or reaction gap heights may be used based on the coating process or precursors or substrates.

In one embodiment, the substrate support is arranged below the precursor supply head such that the support surface of the faces upwards towards the downwards facing output face. The reaction gap is provided between the support surface and the output face. This arrangement may be provided to any of the embodiments of the invention.

In another embodiment, the substrate support is arranged above the precursor supply head such that the support surface of the faces downwards towards the upwards facing output face. The reaction gap is provided between the support surface and the output face. This arrangement may be provided to any of the embodiments of the invention.

Furthermore, in some embodiments the support surface and the output face are arranged in vertical direction or an angle relative to vertical and horizontal direction.

In one embodiment, the moving mechanism is arranged to move the substrate support for moving the substrate support and the precursor supply head relative to each other in the moving direction between the support surface of the substrate support and the output face of the precursor supply head. The advantage of moving substrate support is that there is no need to move gas and precursor connections but they can be provided fixed.

In an alternative embodiment, the moving mechanism is arranged to move the precursor supply head for moving the substrate support and the precursor supply head relative to each other in the moving direction between the support surface of the substrate support and the output face of the precursor supply head. The advantage of moving the precursor supply head is that the moving of the precursor supply head in the moving direction may be connected to opening and closing the apparatus or a vacuum chamber thereof for loading and unloading substrates.

In one embodiment, the moving mechanism is arranged to rotate the substrate support for rotating the support surface of the substrate support and the output face of the precursor supply head are arranged to be rotated relative to each other. The advantage of rotating the substrate support is that there is no need to move gas and precursor connections but they can be provided fixed.

In another embodiment, the moving mechanism is arranged to rotate the precursor supply head for rotating the support surface of the substrate support and the output face of the precursor supply head are arranged to be rotated relative to each other.

In one embodiment of the present invention, the output face of the precursor supply head and the support surface of the substrate support are arranged parallel to each other such that a uniform reaction gap is provided between the support surface of the substrate support and the output face of the precursor supply head, and the moving mechanism is arranged to move the substrate support and the precursor supply head relative to each other in the moving direction extending perpendicularly to the support surface of the substrate support. This allows keeping the reaction gap and reaction gap height uniform during adjusting the reaction gap. Further the substrate support and the precursor supple head may be arranged at different distances from each they for processing and keeping a uniform reaction gap.

In one embodiment, the moving mechanism comprises a rotating axis around which the substrate support and the precursor supply head are arranged to be rotated relative to each other, and the rotating axis is arranged perpendicularly to the support surface, or the rotating axis is arranged parallel to the moving direction.

The rotating axis may be physical axis or it may be an imaginary axis. Accordingly, the moving the substrate support and the precursor supply head relative to each other along the rotating axis enables utilizing the apparatus at different reaction gap heights as the reaction gap remains uniform at different reaction gap heights along the moving direction and direction of the rotating axis.

In one embodiment, the moving mechanism comprises a rotating mechanism arranged to rotate the substrate support and the precursor supply head relative to each, and the moving mechanism comprises a transfer mechanism arranged to move the substrate support and the precursor supply head relative to each other in the moving direction.

In this embodiment, there is separate moving mechanism and rotating mechanism. This enables operating the and controlling the rotating movement and moving the substrate support and the precursor supply head relative each other independently of each other.

In another embodiment, the moving mechanism comprises a rotating mechanism arranged to rotate the substrate support and the moving mechanism comprises a transfer mechanism arranged to move the substrate support in the moving direction.

In this embodiment, the substrates support is arranged to be both rotated and moved along the moving direction. Thus, the precursor supply head is arranged static and fixed such that gas connections are also provided fixed and static.

In one embodiment, the moving mechanism is arranged to move the substrate support in the moving direction. The substrate support comprises a back surface opposite the support surface, and the substrate support further comprises one or more through holes extending through the substrate support between the back surface and the support surface in the moving direction. The apparatus further comprises a loading support extending in the moving direction, the loading support being arranged to fit through the one or more through holes upon moving the substrate support with the moving mechanism in the moving direction and relative to the loading support.

The one or more through holes are open to the support surface of the substrate support and to the back surface of the substrate support. According, the one or more through holes extend between the support surface and the back surface of the substrate support.

Accordingly, the substrate maybe placed from the loading support on the support surface of the substrate support by moving the substrate support in the moving direction towards the precursor supply head, or upwards. Similarly, the substrate maybe removed from the support surface of the substrate support on the loading support by moving the substrate support in the moving direction away from the precursor supply head, or downwards. Thus, placing the substrate on the support surface and removing the substrate form the support surface are carried out with one movement, preferably linear movement.

In one embodiment, the moving mechanism is arranged to move the substrate support in the moving direction to a process position in which the loading support is below the support surface of the substrate support, and the moving mechanism is further arranged to move the substrate support in the moving direction to a loading position in which the loading support is above the support surface of the substrate support. Thus, in the process position the substrate is placed on the support surface of the substrate support and the loading support is below the support surface. Further, in the loading position the substrate is placed on the loading support and the loading support is above the support surface of the substrate support.

In some embodiments, the loading support is provided static and fixed. Thus, the loading support cannot be moved.

In alternative embodiments, the loading support is arranged to be movable in the loading direction. The loading support is provided with the support mechanism arranged to move the loading support in the moving direction.

In one embodiment, the apparatus further comprises a loading device arranged to load and unload substrates to the reaction gap between the support surface of the substrate support and the output face of the precursor supply head.

Use of the loading device is enabled by providing the substrate support and the precursor supply head to be moved in the moving direction relative to each other. The reaction gap height may be increased enabling the substrate to be loading to the reaction gap between the support surface of the substrate support and the output face of the precursor supply head.

In an alternative embodiment, the apparatus further comprises a loading device arranged to load and unload substrates to the reaction gap between the support surface of the substrate support and the output face of the precursor supply head in a loading direction, the loading direction being transverse or perpendicular to the moving direction.

Use of loading direction transverse or perpendicular to the moving direction enables efficient loading and unloading of substrates to the reaction gap. Furthermore, this loading direction and moving substrate holder enable automated loading and unloading without breaking the vacuum.

The present invention further relates to a method for operating an atomic layer deposition apparatus. The apparatus comprises a substrate support having a support surface and arranged to support one or more substrates, a precursor supply head having an output face via which precursors are supplied. The support surface of the substrate support and the output face of the precursor supply head are arranged opposite to each other such that a reaction gap is provided between the support surface of the substrate support and the output face of the precursor supply head. The method comprises rotating the substrate support and the precursor supply head relative to each other with the moving mechanism during processing the one or more substrates such that the support surface of the substrate support and the output face of the precursor supply head are arranged to be rotated relative to each other.

According to the present invention, the method further comprises moving the substrate support and the precursor supply head relative to each other in a moving direction extending between the support surface of the substrate support and the output face of the precursor supply head such that the reaction gap is adjusted for adjusting reaction gap.

Moving the substrate support and the precursor supply head relative to each other in the moving direction enables adjusting the reaction gap or the height of the reaction gap and further arranging the substrate support and the precursor supply head to a process position and loading position relative to each.

In one embodiment of the present invention, the method comprises moving the substrate support relative to the precursor supply head in the moving direction for adjusting reaction gap. The advantage of moving substrate support is that there is no need to move gas and precursor connections but they can be provided fixed.

In an alternative embodiment, the method comprises moving the precursor supply head relative to the substrate support in the moving direction for adjusting reaction gap. The advantage of moving the precursor supply head is that the moving of the precursor supply head in the moving direction may be connected to opening and closing the apparatus or a vacuum chamber thereof for loading and unloading substrates.

In one embodiment, the output face of the precursor supply head and the support surface of the substrate support are arranged parallel to each other such that a uniform reaction gap is provided between the support surface of the substrate support and the output face of the precursor supply head. The method further comprises moving the substrate support and the precursor supply head relative to each other in the moving direction extending perpendicularly to the support surface of the substrate support. The moving direction which is perpendicular to the support surface enables keeping a uniform reaction gap in different positions along the moving direction.

In one embodiment, the method comprises moving the substrate support in the moving direction to a process position in which the reaction gap has a first gap height, and moving the substrate support in the moving direction to a loading position in which the reaction gap has a second gap height, the second gap height being greater than the first gap height. This enables efficient loading and unloading of substrates between the substrate support and the precursor supply head. Thus, there is no need to remove the substrate support or the precursor supply head.

In one embodiment, the method comprises moving the substrate support in the moving direction to the loading position, loading one or more substrates to the reaction gap in a loading direction. The loading direction is transverse or perpendicular to the moving direction. The method further comprises moving the substrate support in the moving direction to the process position.

The transverse or perpendicular loading direction in relation to the moving direction enables efficient loading and unloading of substrates to the reaction gap. Furthermore, this loading direction and moving substrate holder enable automated loading and unloading without breaking the vacuum.

In an alternative embodiment, the method comprises moving the substrate support in the moving direction to the loading position, loading one or more substrates to the reaction gap in a loading direction. The loading direction is transverse or perpendicular to the moving direction. The method further comprises moving the substrate support in the moving direction to the process position, processing the one or more substrates by supplying precursors to the reaction gap via the output face of the precursor supply head, moving the substrate support in the moving direction to the loading position, and unloading the one or more substrates from the reaction gap in the loading direction. Accordingly, loading and unloading of substrates may be carried out with two linear movements in the moving direction and in the loading direction. Thus, the loading and unloading is efficient and may also be automated.

In one embodiment, the substrate support comprises a back surface opposite the support surface, and the substrate support further comprises one or more through holes extending through the substrate support between the back surface and the support surface in the moving direction, and the apparatus further comprises a loading support extending in the moving direction, the loading support being arranged to fit through the one or more through holes upon moving the substrate support with the moving mechanism in the moving direction and relative to the loading support.

The method further comprises moving the substrate support in the moving direction to the loading position in which the reaction gap has the second height and in which the loading support extends through the one or more through holes above the support surface of the substrate support, and moving the substrate support in the moving direction to the process position in which the reaction gap has the first height and in which the loading support is below the support surface of the substrate support.

In an alternative embodiment, the method comprises moving the substrate support in the moving direction to the loading position in which the reaction gap has the second height and in which the loading support extends through the one or more through holes above the support surface of the substrate support, loading a substrate on the loading support in the loading direction, and moving the substrate support in the moving direction to the process position in which the reaction gap has the first height and in which the loading support is below the support surface of the substrate support such that the substrate is placed on the support surface of the substrate support during the moving of the substrate support from the loading position to the process position.

In another embodiment, the method comprises moving the substrate support in the moving direction to the loading position in which the reaction gap has the second height and in which the loading support extends through the one or more through holes above the support surface of the substrate support, loading a substrate on the loading support in the loading direction, moving the substrate support in the moving direction to the process position in which the reaction gap has the first height and in which the loading support is below the support surface of the substrate support such that the substrate is placed on the support surface of the substrate support during the moving of the substrate support from the loading position to the process position. The method further processing the one or more substrates by supplying precursors to the reaction gap via the output face of the precursor supply head, and moving the substrate support in the moving direction to the loading position in which the reaction gap has the second height and in which the loading support extends through the one or more through holes above the support surface of the substrate support such that the substrate is placed on the loading support during the moving of the substrate support from the process position to the loading position.

Accordingly, the substrate maybe placed from the loading support on the support surface of the substrate support by moving the substrate support in the moving direction towards the precursor supply head, or upwards. Similarly, the substrate maybe removed from the support surface of the substrate support on the loading support by moving the substrate support in the moving direction away from the precursor supply head, or downwards. Thus, loading and unloading of the substrate to the apparatus may be carried out with two movements, preferably linear movements.

Preferably, the method of the present invention is carried out with an atomic layer deposition apparatus as disclosed above.

An advantage of the invention is that the providing the substrate support and the precursor supply head movable in relation to each other in the moving direction the reaction gap or height of the reaction may be adjusted. Thus, the reaction gap may be adjusted based on the coating process as well as based on substrates and precursors used in the coating process. Furthermore, adjustable reaction gap enables loading substrates directly between the substrate support and the precursor supply head such that there is no need to remove the precursor supply head or the substrate support. Further, the loading and unloading of substrates may be carried out without breaking vacuum in the apparatus. Adjustable reaction gap also enables automated loading and unloading of substrates into the apparatus and into the reaction gap.

### BRIEF DESCRIPTION OF THE DRAWINGS

The invention is described in detail by means of specific embodiments with reference to the enclosed drawings, in which

FIG. 1 shows schematically an atomic layer deposition apparatus of one embodiment according to the present invention;

FIGS. 2-4 show schematically loading of a substrate to an apparatus according to the present invention;

FIGS. 4-7 show schematically different embodiments of the apparatus according to the present invention;

FIG. 5 shows a schematic top view of one embodiment of a substrate support;

FIGS. 6 and 7 show schematic side views of the support of FIG. 5;

FIG. 8 shows a schematic top view of another embodiment of a substrate support;

FIGS. 9 and 10 shows a schematic side views of the support of FIG. 7;

FIG. 11 shows a schematic top view of one embodiment of a precursor supply head;

FIG. 12 shows a schematic view of one embodiment of a reaction zone according to the present invention.

### DETAILED DESCRIPTION OF THE INVENTION

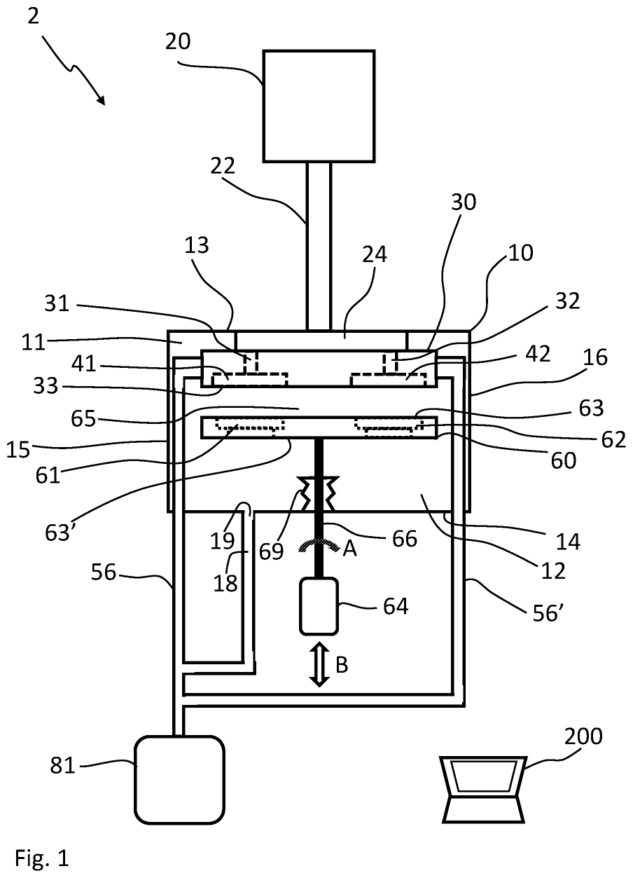

FIG. 1 shows an atomic layer deposition apparatus 2 for processing a surface of a substrate successively with at least a first precursor and a second precursor according to principles of atomic layer deposition. The apparatus comprises a process chamber 10 having a process chamber space 11 inside the process chamber 10. The process chamber 10 comprises process chamber walls 13, 14, 15, 16 defining the process chamber space 11.

The process chamber 10 is provided as a vacuum chamber and connected to a vacuum device or suction device 81. Thus, the process chamber 10 is provided as the process chamber and as the vacuum chamber 10. The suction device 81 may be vacuum pump, suction pump suction device or the like device arranged to provide vacuum or underpressure in the chamber space 11 of the process chamber 10.

The suction device 81 is arranged to provide vacuum or underpressure to the process chamber space 11 inside the process chamber 10. Further, the suction device 81 is arranged to discharge gases from the process chamber space 11 of the process chamber 10.

The suction device 81 is connected to the process chamber 10 with a discharge connection 18, 19 for providing suction or discharge force from the suction device 81 to the process chamber 10.

The discharge connection comprises a discharge opening 19 and a discharge conduit 18 extending between the suction device 81 and the discharge opening 19. The discharge connection 18, 19 and the discharge opening 19 are open to the process chamber space 11 of the process chamber 10.

The suction device 81 is arranged outside the process chamber 10. The discharge connection 18, 19 is provided to the chamber walls 13, 14, 15, 16 of the process chamber 10. The discharge opening 19 is provided to the chamber walls 13, 14, 15, 16 of the process chamber 10 and further the discharge opening 19 is open to the process chamber space 11 of the process chamber 10. The discharge conduit 18 extends from the discharge opening 19.

The discharge conduit 18 extends from the chamber wall or the bottom wall 14 to the suction device 81.

In the embodiment of FIG. 1, the discharge connection 18, 19 is provided to the bottom wall 14 of the process chamber 10. Further, the discharge opening 19 is provided to the bottom wall 14 of the process chamber 10.

In alternative embodiments, the discharge connection 18, 19 and the discharge opening 19 is arranged to other walls of the process chamber 10, such as the side walls 15, 16 or the top wall 13.

In an alternative embodiment, there is a separate vacuum chamber (not shown) surrounding the process chamber 10. Thus, the process chamber 10 is provided inside the vacuum chamber. The vacuum chamber is connected to the vacuum device for providing vacuum inside the vacuum chamber.

The substrates are processed inside the process chamber 10.

The apparatus 2 further comprises a substrate support 60 having a support surface 63 and arranged to support one or more substrates on the support surface 63. The substrate support 60 is arranged to support and hold one or more substrates during processing the substrates with the apparatus 2.

The substrate support 60 is provided inside the process chamber 10. Thus, the substrate support 60 is inside the process chamber space 11.

The support surface 63 is planar surface extending on a plane.

The substrates are arranged on the or in connection with the support surface 63. Preferably, the substrates are planar or plate-like substrates having two main substrate surfaces, such as silicon wafers.

The substrates are usually supported to the substrate support 60 such that the substrate surface or main substrate surface is parallel to the support surface 63.

The substrate support 60 comprises one or more substrate holders 61, 62 arranged to secure and hold one or more substrates during processing. The substrate holders 61, 62 are provided to the support surface 63 or in connection with the support surface 63.

One substrate holder 61, 62 is arranged to hold one substrate.

The substrates are supported to the support surface 63 such that the upper surface facing away from the support surface 63 is flush with or at the level of the support surface 63.

In some alternative, embodiments the substrates are supported to the support surface 63 such that the upper surface facing away from the support surface 63 is below the support surface 63.

Further, in some embodiments, substrates are supported to the support surface 63 such that the upper surface facing away from the support surface 63 is above the support surface 63. In these embodiments, the substrates may also be support directly on the support surface 63.

The substrate support 60 further comprises back surface 63′ on opposite side of the substrate support 60 in relation to the support surface 63.

The substrate holders 61, 62 for holding the substrates are provided with a through hole extending through the substrate support 60 from the support surface 63 to the back surface 63′.

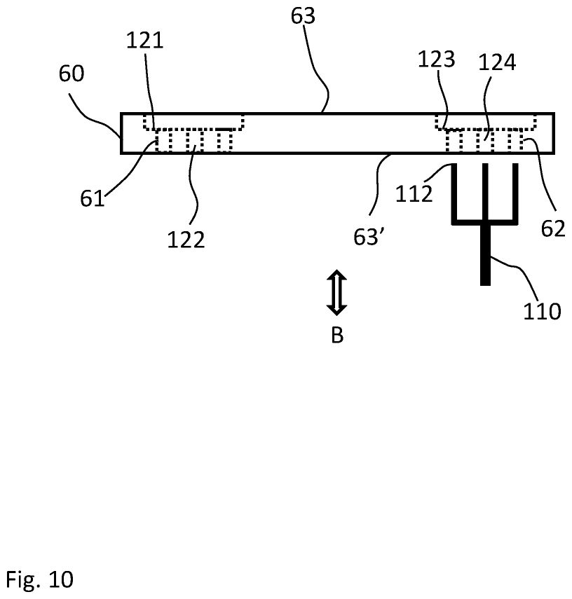

The apparatus of the present invention further comprises a precursor supply head 30 having an output face 33. The output face 33 is provided with at least one gas distribution element 41, 42 via which precursors are supplied. The one or more gas distribution elements 41, 42 provide one or more reaction zones 44, 44′, respectively, or form one or more reaction zones 44, 44′, as shown later in connection with FIG. 10.

The precursor supply head 30 is provided inside the process chamber Thus, the precursor supply head 30 is inside the process chamber space 11.

As shown in FIG. 1, the support surface 63 of the substrate support 60 and the output face 33 of the precursor supply head 30 are arranged opposite to each other. The support surface 63 and the output face 33 are spaced apart from each other such that a reaction gap 65 is provided between the support surface 63 and the output face 33.

In the embodiments of figures, the substrate support is arranged below the precursor supply head such that the support surface of the faces upwards towards the downwards facing output face. However, the apparatuses may also be modified such that the substrate support is arranged above the precursor supply head such that the support surface of the faces downwards towards the upwards facing output face.

Precursors are supplied via the output face 33 towards the support surface 63 and the substrates are arranged to the support surface 63 during processing. Further, precursors are supplied from the one or more gas distribution elements 41, 42, or one or more reaction zones 44, 44′ towards the support surface 63 via the reaction gap 65. Therefore, during processing the precursors, as well as possible purge gas, travel in the reaction gap 65 towards or against the support surface 63 and the substrates supported to the support surface 63.

The output face 33 of the precursor supply head 30 and the support surface 63 of the substrate support 60 are arranged parallel to each other. The parallel output face 33 and the support surface 63 together form a uniform reaction gap 65. The uniform reaction gap 65 means that the distance between the output face 33 and the support surface 33 is constant in the area between the output face 33 and the support surface 63.

In the embodiment of the FIG. 1, the substrate support 60 is arranged in vertical direction below precursor supply head 30. Further, the support surface 63 is arranged in vertical direction below the output face 33. Accordingly, the precursors and possible purge gas are supplied from the precursor supply head 30 via the output face 33 downwards and towards the support surface 63.

The gas distribution elements 41, 42 and the reaction zones 44, 44′ are provided to the output face 33 or in connection with the output face 33 such that precursors are supplied via the output face 33.

The precursor supply head 30 is connected to a precursor supply system 20. The precursor supply system 20 comprises precursor sources (not shown), such as precursor containers or the like, and one or more pumps and valves (not shown) for supplying precursors to the precursor supply head 30 via supply conduits 22, 24.

The precursor supply system 20 may also comprise purge gas sources (not shown), such as purge gas containers or the like, and one or more pumps and valves (not shown) for supplying purge gas to the precursor supply head 30 via the supply conduits 22, 24.

The supply conduits 22, 24 comprise one or more precursor conduits, one for each precursor. The precursor conduits are connected to the precursor sources in the precursor supply system 20.

Further, the gas distribution elements 41, 42, or the reaction zones 44, 44′ thereof, comprise precursor supply zones or precursor supply nozzles for supplying precursors via the precursor supply head 30.

The supply conduits 22, 24 further comprise one or more purge gas conduits. The purge gas conduits are connected to the purge gas sources in the precursor supply system 20.

Further, the gas distribution elements 41, 42, or the reaction zones 44, 44′ thereof, comprise purge gas zones or purge gas nozzles for supplying purge gas via the precursor supply head 30.

As shown in FIG. 1, the precursor supply system 20 is arranged outside of the process chamber 10. The supply conduits 22, 24 extends between the precursor supply system 20 and the precursor supply head 30. Accordingly, the supply conduits 22, 24 extend from outside the process chamber 10 through the chamber walls into the process chamber 10 and further to the precursor supply head 30.

At least one of the reaction zones 44, 44′ may comprise a plasma discharge arrangement arrange to provide plasma discharge during the precursor supply.

In embodiments comprising the separate vacuum chamber surrounding the process chamber 10, the precursor supply system 20 is arranged outside of the vacuum chamber. Accordingly, the supply conduits 22, 24 extend from outside the vacuum chamber through the vacuum chamber walls into the vacuum chamber and further through the process chamber walls into the process chamber 10 and to the precursor supply head 30.

The precursor supply head 30 comprises supply channels 31, 32 for the precursors, purge and suction.

The supply channels 31, 32 are connected to the corresponding supply conduits 22, 24. Further, the supply channels 31, 32 of the precursor supply head 30 are connected to the one or more gas distribution elements 41, 42, or one or more reaction zones 44, 44′, respectively, of the precursor supply head 30.

The supply channels 31, 32 may comprise one or more precursor supply channels, for supplying precursors. The precursor supply channels are connected to the one or more gas distribution elements 41, 42, or one or more reaction zones 44, 44′, respectively. Each precursor may be provided with a separate precursor supply channel. The precursor supply channels are connected between the one or more gas distribution elements 41, 42, or one or more reaction zones 44, 44′, respectively, and the precursor supply conduits of the supply conduit 22.

The supply channels 31, 32 may comprise one or more purge gas supply channels, for supplying purge gas. The purge gas supply channel(s) are connected to the one or more gas distribution elements 41, 42, or one or more reaction zones 44, 44′, respectively. The purge gas supply channels are connected between the one or more gas distribution elements 41, 42, or one or more reaction zones 44, 44′, respectively, and the purge gas supply conduits of the supply conduit 22.

According to the above mentioned, gas exchange between the precursor supply system 20 and the one or more gas distribution elements 41, 42, or one or more reaction zones 44, 44′, is carried out via the supply conduits 22, 24 and the supply channels 31, 32.

The apparatus further comprises one or more suction connections 56, 56′ connected to the precursor supply head 30 and to the gas distribution elements 41, 42, or reaction zones 44, 44′, thereof.

Further, the gas distribution elements 41, 42, or the reaction zones 44, 44′ thereof, comprise suction zones or suction nozzles for discharging gases via the precursor supply head 30.

The suction connections 56, 56′ are connected to the suction device 81 for providing a suction force via the gas distribution elements 41, 42, or the reaction zones 44, 44′ thereof. The suction device 81 provides suction or suction force via the suction zones of the precursor supply head 30 and the gas distribution elements 41, 42 thereof to the reaction gap 65.

In the embodiment of FIG. 1, the suction device 81 is common suction device connected to suction connections 56, 56′, and the suction zones, and to the discharge connection 18, 19 for providing suction to the reaction gap 65 and to the chamber space 11 outside the reaction gap 65.

The suction zones or suction nozzles are open to the output face 33 of the precursor supply head 30.

The suction connections 56, 56′ comprise suction conduits 56, 56′ extending from the precursor supply head 30, and the gas distribution elements 41, 42, or the reaction zones 44, 44′ thereof. The suction conduits 56, 56′ are further connected to the suction device 81.

The suction conduits 56, 56′ extend from the precursor supply head 30 and out of the process chamber 10. As shown in FIG. 1, the suction device 81 is arranged outside the process chamber 10. The suction conduits 56, 56′ extend between the suction device 81 and the precursor supply head 30. Accordingly, the suction conduits 56, 56′ extend from outside the process chamber 10 through the chamber walls into the process chamber 10 and further to the precursor supply head 30.

In the embodiment of FIG. 1, each gas distribution element 41, 42, or reaction zone 44, 44′ thereof, comprises a separate suction connection 56, 56′ or suction conduit 56, 56′, respectively.

The suction conduits 56, 56′ are arranged to extend into the process chamber space 11 through the bottom wall 14 of the process chamber 10 in the embodiment of FIG. 1. Accordingly, the suction device 81 is arranged outside the process chamber 10 and the suction conduits 56, 56′ extend from the precursor supply head 30 through the bottom wall 14 of the process chamber 10 to the suction device 81.

In alternative embodiment, the suction conduits 56, 56′ are provided to other walls of the process chamber 10, such as the side walls 15, 16 or the top wall 13.

In an alternative embodiment, the suction conduit(s) 56, 56′ are provided in connection with the supply conduit(s) 20 of the precursor supply system 20. Thus, no additional lead-thoughts to the process chamber 10 are needed.

Preferably, the discharge connection 18, 19 and the suction connection 56, 56′, or suction conduits 56, 56′, are provided to the bottom wall 14 of the process chamber 10 and the precursor supply conduits 22, 24, precursor supply connections 22, 24, are provided to the top wall 13 or in connection with the top wall 13 of the process chamber 10.

As shown in FIG. 1, the substrate support 60 is arranged in vertical direction below the precursor supply head 30 in the process chamber 10, and the discharge connection 18, 19 is provided below the support surface 63 of the substrate support 60 inside the process chamber 10. Further, the discharge connection 18, 19 is provided below the substrate support 60 in the process chamber 10.

The discharge connection is arranged below the substrate support in the processing position of the substrate support.

Further, the discharge connection 18, 19 is open to the chamber space 11 outside the reaction gap 65. The suction connections 56, 56′ are open to the reaction gap 65.

In the embodiment of FIG. 1, the apparatus 2 comprises a substrate processing unit 30, 60, 65 comprising the substrate support 60, the precursor supply head 30 and the reaction gap 65 between the support surface 63 of the substrate support 60 and the output face 33 of the precursor supply head 30. The process chamber 10 comprises an intermediate chamber space 12 surrounding the substrate processing unit 30, 60, 65 inside the chamber space 11 of the process chamber 10. The discharge connection 18, 19 is open to the intermediate chamber space 12.

The suction connections 56, 56′ are open into the processing unit 30, 65, or to the reaction gap 65 inside the processing unit 30, 60, 65. Thus, the suction connections 56, 56′ subject the suction force into the reaction gap 65 inside the processing unit 30, 60, 65.

Preferably, the discharge connection 18, 19 is open to the intermediate chamber space 12 in vertical direction below the substrate processing unit 30, 60, Thus, the discharge connection 18, 19 subjects the suction force to the intermediate space 12 surrounding the processing unit 30, 60, 65. Further, the discharge connection 18, 19 subjects the suction force outside the reaction gap 65.

In the embodiment of FIG. 1, the discharge connection 18, 19 is arranged below the substrate support 60 in the processing position of the substrate support 60.

In the embodiment of FIG. 1, the precursor supply head 30 comprises a first gas distribution element 41 and a first reaction zone 44. A first suction zone is provided to the first gas distribution element 41 and the first reaction zone 44. Further, a first suction conduit 56 is arranged to extend form the first suction zone, or the first gas distribution element 41 and the first reaction zone 44 to the suction device 81. The suction device 81 is arranged outside the process chamber 10 and the first suction conduit 56 extends from the precursor supply head 30 and the from the first gas distribution element 41 through the bottom wall 14 of the process chamber 10 to the suction devices 81.

Further, the precursor supply head 30 comprises a second gas distribution element 42 and a second reaction zone 44′. A second suction zone is provided to the second gas distribution element 42 and the second reaction zone 44′. Further, a second suction conduit 56′ is arranged to extend form the second suction zone, or the second gas distribution element 42 and the second reaction zone 44′ to the suction device 81. The suction device 81 is arranged outside the process chamber 10 and the second suction conduit 56′ extends from the precursor supply head 30 and the from the second gas distribution element 42 through the bottom wall 14 of the process chamber 10 to the suction devices 81.

The apparatus 2 may further comprises control unit 200. The control unit may be computer or the like control unit. The control unit 200 may comprise at least one processor and a memory.

The control unit 200 is configured to control operation of the apparatus 2. The control unit 200 is arranged to control the precursor supply and operation of the precursor supply system 20. Further, the control unit 200 is arranged to control operation of the suction devices 81.

The discharge force via the discharge connection 18, 19 is preferably provided greater than the suction forces via the gas distribution elements 41, 42, or the reaction zones 44, 44′ thereof.

In some embodiments, the discharge force via the discharge connection 18, 19 is greater than the sum of the suction forces via the first and second gas distribution elements 41, 42, or the reaction zones 44, 44′ thereof, form the first and second suction connections 56, 56′.

According to the present invention, the precursor supply head 30 and the substrate support 60 are rotated in relation to each other around a rotation axis 66.

In the embodiment of FIG. 1, the substrate support 60 is rotated around the rotation axis 66.

The rotation axis 66 extends perpendicularly to the output face 33 and the support surface 63. Therefore, the reaction gap 65 is maintained constant during the rotation.

In the embodiment of FIGS. 1 to 4, the rotation axis 66 is connected to the substrate support 60 and arranged to rotate the substrate support 60.

Alternatively, the rotation axis 66 is connected to the precursor supply head 30 and arranged to rotate the precursor supply head 30.

During the rotation, the substrates supported to the support surface 63 travel in rotational motion in relation to the one or more gas distribution elements 41, 42, or one or more reaction zones 44, 44′, respectively, of the precursor supply head 30. Thus, the substrates are successively subjected to the precursors supplied via the one or more gas distribution elements 41, 42, or one or more reaction zones 44, 44′, respectively, of the precursor supply head 30 due to the relative rotational movement. During the rotation, the substrates travel past the one or more gas distribution elements 41, 42, or one or more reaction zones 44, 44′, respectively, of the precursor supply head 30 and are thus subjected to the precursors.

The apparatus 2 comprises a moving mechanism 64, 66. The substrate support 60 and the precursor supply head 30 are arranged to be rotated relative to each other with the moving mechanism 64, 66. The substrate support 60 and the precursor supply head 30 are arranged to be rotated relative to each other with the moving mechanism 64, 66 such that the support surface 63 of the substrate support 60 and the output face 33 of the precursor supply head 30 are arranged to be rotated relative to each other.

In the embodiment of FIG. 1, the moving mechanism 64, 66 or the rotating device 64 is connected to the substrate support 60 for rotating the substrate support 60. The moving mechanism 64 comprises a rotating motor or the like device arranged to output rotating movement to the substrate support 60 or to the rotation axis 66.

The moving mechanism 64 is connected to the substrate support 60 with the rotation axis 66 arranged to transfer rotating movement from the moving mechanism 64 to the substrate support 60. The moving mechanism 64 and the rotation axis 66 are arranged to rotate the substrate support 60 in rotation direction A.

The rotation axis 66 extends perpendicularly to the support surface 63.

Accordingly, the rotation axis 66 extends in vertical direction.

It should be noted, that the rotation axis 66 may be any kind of axis or element arranged to transfer rotation from the moving mechanism 64 to the substrate support 60.

As shown in FIG. 1, the moving mechanism 64 is arranged outside the process chamber 10. The rotation axis 66 extends between the rotating device 64 and the substrate support 60. Accordingly, the rotation axis 66 extends from outside the process chamber 10 through the chamber walls into the process chamber 10 and further to the substrate support 60. The lead-through for the rotation axis is provided with bellows 69. The bellows 69 is connected to the chamber wall, or bottom wall 14, and to the rotation axis 66 allowing movement of the rotation axis 66 in relation to the process chamber 10 and the bottom wall 14 such that vacuum tight lead-through for the rotation axis 66 provided.

The moving mechanism 64 is arranged in vertical direction below the substrate support 60. As shown in FIG. 1, the rotation axis 66 extends from outside the process chamber 10 through the bottom wall 14 of the process chamber 10 into the process chamber space 11 and to the substrate support 60.

In embodiments comprising the separate vacuum chamber surrounding the process chamber 10, the rotating device 64 is arranged outside of the vacuum chamber. Accordingly, the rotation axis 66 extends from outside the vacuum chamber through the vacuum chamber walls into the vacuum chamber and further through the process chamber walls into the process chamber 10 and to the substrate support 60.

The moving mechanism 64, 66 is further arranged to move the substrate support 60 for moving the substrate support 60 and the precursor supply head 30 relative to each other in a moving direction B between the support surface 63 of the substrate support 60 and the output face 33 of the precursor supply head 30. The moving mechanism 64, 66 is arranged to move the substrate support 60 in the moving direction B inside the process chamber 10. Therefore, the moving mechanism 64, 66 is arranged to move the substrate support 60 towards precursor supply head 30 and away from the precursor supply head 30. Further, the moving mechanism 64, 66 is arranged to move the support surface 63 towards output face 33 and away from the output face 33.

Further, the moving mechanism 64, 66 is arranged to move the substrate support 60 relative to the precursor supply head 40 in the moving direction B extending perpendicularly to the support surface 63 of the substrate support 60.

Therefore, the moving mechanism 64, 66 is arranged to move the substrate support 60 relative to the precursor supply head 40 in the direction of the rotating axis 64. Thus, the rotating axis 64 is arranged parallel to the moving direction.

In the embodiment of FIG. 1, the moving mechanism 64, 66 is arranged to move the rotation axis 66 in the moving direction B and thus also the substrate support 30 connected to the rotation axis 66.

The moving mechanism 64, is further arranged to move the substrate support in vertical direction, or in up and down direction.

In the embodiment of FIG. 1, the moving mechanism 64 comprises a rotating mechanism, or rotating device, arranged to rotate the substrate support in the rotation direction A, and a transfer mechanism, or transfer device, arranged to move the substrate support 60 in the moving direction B. Accordingly, the moving mechanism 64 is arranged to both rotate the substrate support 60 and moving substrate support 60 in the moving direction B.

Moving the substrate support 60 in the moving direction enables adjusting the reaction gap 65 or height of the reaction gap 65.

Further, moving the substrate support 60 in the moving direction enables placing the substrates support to a loading position in which substrates are loaded on the support surface 33 between the substrate support 60 and the precursor supply head 30. The substrate support is then moved in the moving direction to a process position for operating the apparatus for processing the surface of the substrate with atomic layer deposition by rotating the substrate support 60 and supplying precursors from the precursor supply head 30 towards the surface of the substrate in the reaction gap 65.

In the process position the reaction gap 65 has a first reaction gap height, and in the loading position the reaction gap 65 has a second reaction gap height. The second reaction gap height is greater than the first reaction gap height. Accordingly, in the loading position the substrate support 60 and the support surface 63 thereof is further away from the precursor supply head 30 and the output face 33 thereof enabling loading and unloading substrate to and from between the substrate support 60 and the precursor supply head.

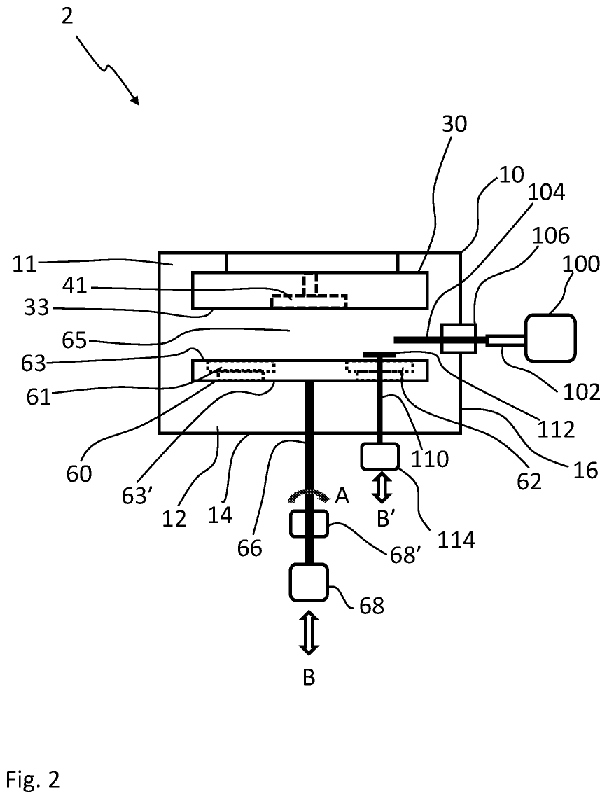

FIG. 2 shows one embodiment of the apparatus according to the present invention. In this embodiment, the moving mechanism comprises a separate rotating mechanism 68′, or rotating device, arranged to rotate the substrate support 60 in the rotation direction A. The rotating mechanism 68′ is connected to the rotation axis 66 and provided outside the process chamber 10.

The moving mechanism further comprises a separate transfer mechanism 68 arranged to move the substrate support 60 in the moving direction. The transfer mechanism 68 is connected to the rotation axis 66 and arranged outside the process chamber 10.

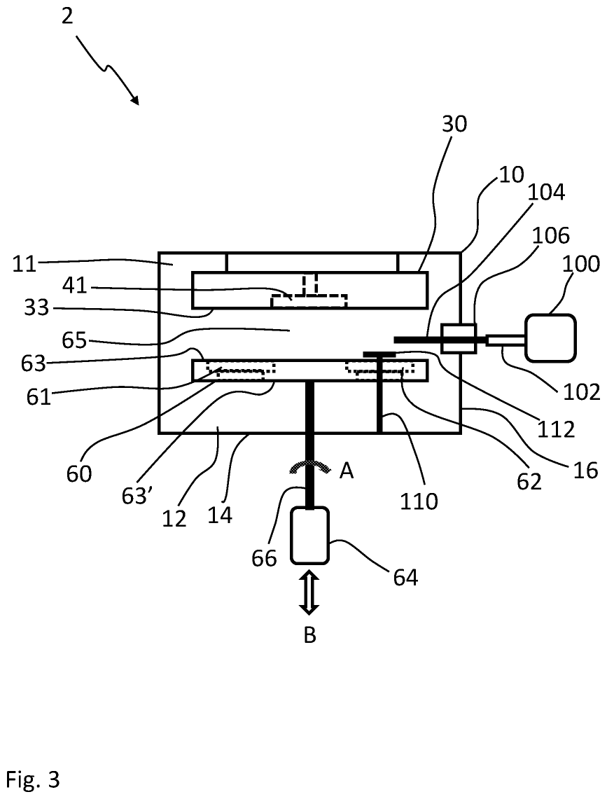

In FIG. 3 is shown an embodiment corresponding the embodiment of FIG. 2, but in there are one moving mechanism 64 comprising the rotating mechanism and the transfer mechanism, or rotating device and transfer device.

Further, in the embodiment of FIG. 3, the loading support 110, 112 is provided as static or fixed loading support 110, 112. Accordingly, the loading support 110, 112 is static and fixed in the process chamber 10 such that it is not movable.

In the embodiments of FIGS. 2 and 3, the substrate support 60 is moved to the loading position in the moving direction B. Thus, the substrate support 60 is moved downwards in the moving direction B away from the precursor supply head. In the loading position the reaction gap 65 has the second reaction gap height.

The apparatus 2 further comprises a loading support 110, 112 provided inside the process chamber 10. The loading support 110, 112 extends in the moving direction B. The loading support 110, 112 is provided with support mechanism 11 arranged to move the loading support 110 in direction B′. The direction B′ is parallel to the moving direction B. The support mechanism 114 comprises a motor or the like device arranged to move the loading support 110, 112. The support mechanism is arranged outside the process chamber 10 and connected to the loading support 110, 112. Thus, the loading support 110, 112 is arranged to be movable in the loading direction B.

In the embodiment of FIGS. 2 to 4, the loading support 110, 112 comprises a support rod 110 connected to the bottom wall 14 of the process chamber 10 and arranged to extend upwards from the bottom wall 14 in vertical direction, or in the moving direction B.

The loading support 110, 112 further comprises a support end 112 provided to the upper end, or distal end, of the support rod 110. The support end 112 comprises an end surface against which a substrate may be supported.

It should be noted that in alternative embodiment there may be more than one loading supports 110, 112.

Further, in the embodiment of FIGS. 2 to 4 the support end 112 is provided as a plate. In an alternative embodiment, the support end 112 may be provided with three or more end pins to which the substrate is supported.

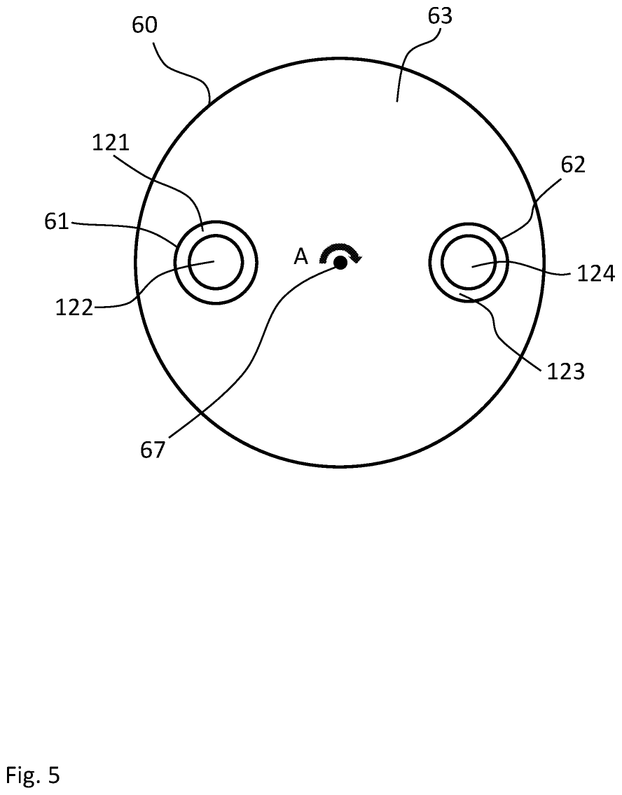

The substrate support 60 comprises a back surface 63′ opposite the support surface 63, and the substrate support 60 further comprises one or more through holes 122, 124 extending through the substrate support 60 between the back surface 63′ and the support surface 63 in the moving direction, as shown in FIGS. 5 to 9.

In the embodiment of FIGS. 1 to 4, the through-holes 122, 124 are provided to the substrate holders 61, 62 or in connection with the substrate holder 61, 62.

The loading support 110, 112 is arranged to fit through the one or more through holes 122, 124 upon moving the substrate support 60 with the moving mechanism 64, 68, 68′ in the moving direction B to the loading position.

Alternatively, the support end 112 is arranged to fit through the one or more through holes 122, 124 upon moving the substrate support 60 with the moving mechanism 64, 68, 68′ in the moving direction B to the loading position.

The loading mechanism 114 may also be arranged to move only the support end 112 in direction B′, for example telescopically.

In the loading position the loading support 110, 112 is above the support surface 63 of the substrate support 60, as shown in FIGS. 2 and 3.

Alternatively, in the loading position the upper or distal end or the support end 112 of the loading support 110, 112 is above the support surface 63 of the substrate support 60.

The one or more through holes 122, 124 extend between the support surface 63 and the back surface 63′ of the substrate support 60. The one or more through holes 122, 124 are open to the support surface 63 and to the reaction gap 65 between the support surface 63 and the output face 33. The one or more through holes 122, 124 are open to the process chamber space 11 or to the intermediate chamber space 12.

The one or more through holes 122, 124 extend between the reaction gap 65 and the process chamber space 11 or the intermediate chamber space 12.

The process chamber 10 is further provided with loading lead-through connection 106 arranged to the process chamber wall. The loading lead-through connection 106 is arranged to enabled loading and unloading of substrates into and from the process chamber 10 without breaking the vacuum conditions of the process chamber 10 or without need to open the process chamber 10.

In some embodiments, the loading lead-through connection 106 is provided as a gate valve or the like valve arrangement arranged to enabled loading and unloading of substrates into and from the process chamber 10 without breaking the vacuum conditions of the process chamber 10.

In the embodiments of FIGS. 2 to 4, the loading lead-through connection 106 is provided to a side wall 16 of the process chamber 10 for loading and unloading of substrates via the side wall 16 into and from the process chamber 10.

The apparatus 2 further comprises a loading device 100 arranged to load and unload substrates into and from the process chamber 10. The loading device 100 may be a loading robot or the like automated device. The loading device 100 may be operated with the control unit 200.

The loading device 100 comprises a loading arm 102 having an end effector 104. The end effector 104 is a movable or extendable arm or robot arm which is arranged to be transferred into the process chamber 10 and out of the process chamber 10 via the loading lead-through connection 106. The substrate to be loaded is placed on the end effector 104 or is arranged to the end effector 104 and the loading device 100 is arranged to transport the substrate from outside the process chamber 10 to the substrate holder 61, 62 of the substrate support 60 via the loading lead-through connection 106. Similarly, the substrate to be unloaded is placed on the end effector 104 or is arranged to the end effector 104 and the loading device 100 is arranged to transport the substrate from inside the process chamber 10 and from the substrate holder 61, 62 of the substrate support 60 via the loading lead-through connection 106 outside the process chamber 10.

The support mechanism 114 of embodiment of FIG. 2 may be utilized for placing the substrate to the end effector 104 and for taking the substrate form the end effector.

Thus, in one embodiment the loading of the substrate comprises end effector 104 is arranged to transport the substrate to the reaction gap 65 over the loading support 110, 112 when the substrate support is in loading position, the loading support 110, 112 is moved upwards in the loading direction B with the support mechanism 114 such that the substrate is supported on the loading support 110, 112, then the end effected is retracted from the process, chamber 10. Further, the substrate is lowered with the support mechanism 114 by moving the loading support 110, 112. When unloading the substrate the substrate support 60 is first moved to the loading position, and the substrate is further raised upwards with the support mechanism 110, 112 by moving the loading support 110, 112. Then, the end effector 104 is transferred to the process chamber 10, the loading support 110, 112 is lowered such that the substrate is placed on the end effector 104. Then, the end effector 104 is retracted form the process chamber 10 and the substrate is removed from the process chamber 10.

FIGS. 2 and 3 show the apparatus 2 and the substrate support 60 in loading position. In the loading position the substrate support 60 is moved or lowered downwards away from the precursor supply head 30 with the moving mechanism 64, 68, 68′. The substrate support 60 is arranged and rotated with the rotating device or the moving mechanism 64, 68, 68′ to position in which the substrate holder 62 is aligned with the loading support 110, 112. Then, the substrate support 60 is lowered downwards to the loading positon with the moving mechanism 64, 68, 68′ the loading support 110, 112 protrudes through the through hole of the substrate holder 62 and support end 112 is above the support surface 63. Thus, in the loading position the loading support 110, 112 protrudes through the through hole of the substrate holder 62.

In the loading position the loading device 100 is arranged to transport a substrate with the end effector 104 via the loading lead-through connection 106 into the process chamber 10 and place the substrate on the loading support 110, 112 and the support end 112, as shown in FIGS. 2 and 3. The upper surface of the support end 112 is towards the precursor supply head 30. Then, the end effector 104 is removed or retracted form the process chamber 10 via the loading lead-through connection 106.

The loading device 100 is arranged to load and unload substrates 200 to and from the reaction gap 65 between the support surface 63 of the substrate support 60 and the output face 33 of the precursor supply head 30. Furthermore, the loading device 100 is arranged to load and unload substrates 200 to the reaction gap 65 between the support surface 63 of the substrate support 60 and the output face 33 of the precursor supply head 30 in a loading direction. The loading direction is transverse or perpendicular to the moving direction B.

The loading direction is preferably horizontal direction as the moving direction is vertical direction.

The loading direction perpendicular to the moving direction B enables efficient loading and unloading and utilization of the loading support 110, 112 as well the movable substrates support 60.

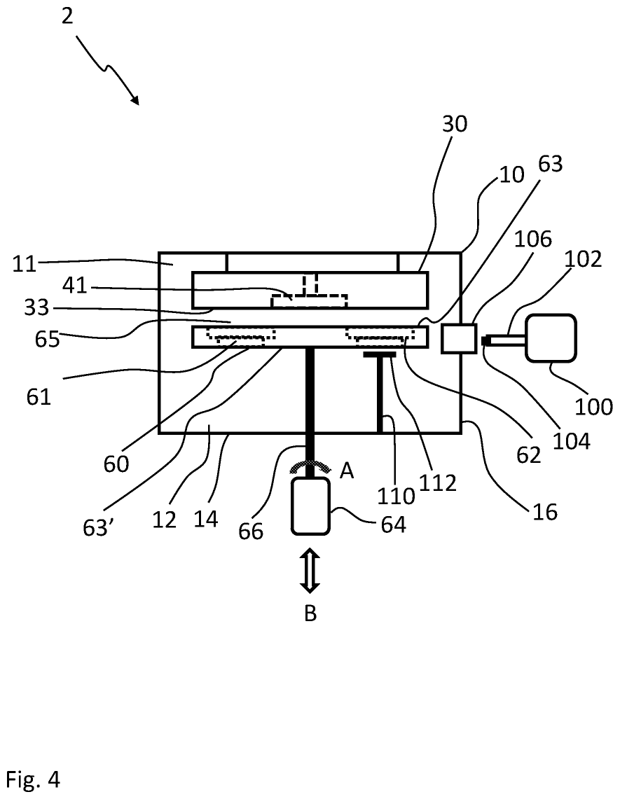

Then, when the substrate is placed on the support end 112 and the end effector 104 is removed or retracted from the process chamber 10, the substrate support 60 is moved or raised upwards with the moving mechanism 64, 68, 68′ towards the precursor supply head 30 and to the process position in which the support surface 63 of the substrate support 60 is close to the output face 33 of the precursor supply head 30 such that the reaction gap 65 is formed, as shown in FIG. 4.

When the substrate support 60 is raised, the loading support 110, 112 leaves the substrate holder 62 and the through hole thereof and at the same time the substrate is set down or placed on the support surface 63 and the substrate holder 62 from the loading support 110, 112 for supporting the substrate during processing to the substrate support 60.

In the process position the loading support 110, 112 is below the support surface 63 of the substrate support 60 below a substrate support surface of the substrate holder 62. Alternatively, in the process position the support end 112 is below the support surface 63 of the substrate support 60 or below a substrate support surface of the substrate holder 62.

Then the substrate may be processed in the process chamber 10.

When substrates are unloaded from the process chamber 10, the substrate support 60 is first lowered and moved downwards to the loading position with the moving mechanism such that the loading support 110, 112 or the support end 112 thereof extends through the substrate holder 62 and the through hole thereof. As the loading support 110, 112 extends through the substrate holder 62 and the through hole thereof, the substrate is placed on the support end 112 from the substrate holder 62, as shown in FIGS. 2 and 3. Then the end effector 104 of the loading device 100 is transferred into the process chamber 10 via the loading lead-through connection 106 and the substrate is removed from the lifting pin end 112 with the end effector 104. Them the end effector 104 moved or retracted from the process chamber 10 together with the substrate.

The present invention provides a method which comprises rotating the substrate support 60 relative to the precursor supply head 30 with the moving mechanism 64, 68, 68′, 66 during processing the one or more substrates such that the support surface 63 of the substrate support 60 and the output face 33 of the precursor supply head 30 are rotated relative to each other. The method further comprises moving the substrate support 60 relative to the precursor supply head in a moving direction extending between the support surface 63 of the substrate support 60 and the output face 33 of the precursor supply head 30 such that the reaction gap 65 is adjusted for adjusting reaction gap 65.

Further, as shown in FIGS. 1 to 4, the method comprises moving the substrate support 60 relative to the precursor supply head 30 in the moving direction extending perpendicularly to the support surface 63 of the substrate support 60.

In the method, the substrate support 60 is moved in the moving direction to the process position in which the reaction gap 65 has a first reaction gap height, and to the loading position in which the reaction gap 65 has a second reaction gap height. The second gap height is greater than the first gap height.

Accordingly, the method comprises moving the substrate support 60 in the moving direction to the loading position, loading one or more substrates 200 to the reaction gap 65 in the loading direction and on the loading support 110, 112, and moving the substrate support 60 in the moving direction to the process position and placing the substrate 200 simultaneously on the support surface 63 or substrate holder 61, 62 of the substrate support 60.

Then, the method comprises processing the one or more substrates by supplying precursors to the reaction gap 65 via the output face 33 of the precursor supply head 30 for subjecting the surface of the substrate 200 to precursors. After processing the substrate, the method comprises moving the substrate support 60 in the moving direction to the loading position such that the loading support 110, 112 protrudes through the substrate support 60 above the support surface 63 and the substrate 20 is lifted from the support surface 63 on the loading support 110, 112. Then the one or more substrates 200 are unloaded from the reaction gap 65 and from the loading support 110, 112 in the loading direction.

Accordingly, the method comprises moving the substrate support 60 in the moving direction to the loading position in which the reaction gap 65 has the second height and in which the loading support 110, 112 extends through the one or more through holes above the support surface 63 of the substrate support 60, loading a substrate 200 on the loading support 110, 112 in the loading direction, and then moving the substrate support 60 in the moving direction to the process position in which the reaction gap 65 has the first height and in which the loading support 110, 112 is below the support surface 63 of the substrate support 60 such that the substrate 200 is placed on the support surface 63 of the substrate support during the moving of the substrate support 60 from the loading position to the process position. Then, the one or more substrates are processed by supplying precursors to the reaction gap 65 via the output face 33 of the precursor supply head 30, and after the processing the substrate support 60 is moved in the moving direction to the loading position in which the reaction gap 65 has the second height and in which the loading support 110, 112 extends through the one or more through holes above the support surface 63 of the substrate support 60 such that the substrate 200 is placed on the loading support 110, 112 during the moving of the substrate support 60 from the process position to the loading position.

FIGS. 5 to 7 show schematically the substrate support 60.

FIG. 5 shows a top view of one embodiment of the substrate support 60. The substrate support 60 and the support surface 63 has a support centre point 67 or support central axis 67. The support centre point 67 is the centre point of the circular support surface 63.

The rotating axis 66 may be connected to the substrate support 60 at the support centre point 67 or along the support central axis 67. Thus, the substrate support 60 and the support surface 63 are rotated in the rotation direction A around the rotation axis 66 and the support centre point 67 or the support central axis 67.

The substrate support 60 comprises two substrate holders 61, 62 provided on the support surface 63 for holding two substrates. Each of the substrate holders 61, 62 are arranged to receive and hold one substrate. The substrate support 60 comprises one or more substrate holders 61, 62.

The substrate holders 62 are arranged to the support surface 63 opposite to each other on opposite sides of the support centre point 67.

The substrate holders 61, 62 are arranged successively or adjacent to each other in the rotation direction A. Thus, the substrate holders 62 are at the same distance from the support centre point 67.

The substrate holders 61, 62 comprise a through hole 122, 124 extending between the support surface 63, or the upper surface of the substrate support 60, and the back surface 63′, lower surface, of the substrate support 60.

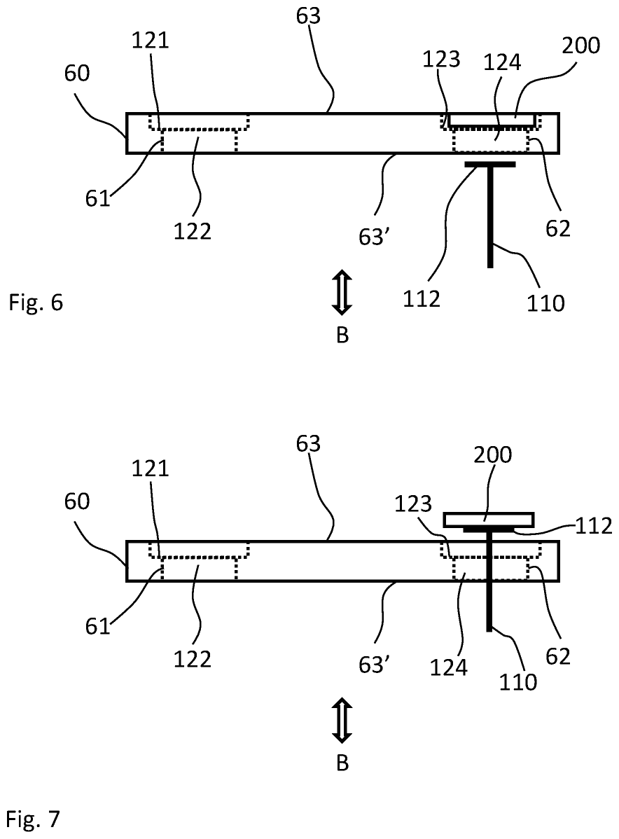

FIGS. 6 and 7 show side views of the substrate support 60 of FIG. 5. The substrate holders 61, 62 are formed as substrate holder recesses provided on the support surface 63 for receiving one or more substrates, respectively. The substrate holders 61, 62 further comprise a holder surface 121, 123 against which the substrate is supported in the substrate holder recess 61, 62. The holder surface 121, 123 is below the support surface 63 towards the back surface 63′ such that the substrate holder recess is formed.

The holder surface 121, 123 is parallel to support surface 63.

The through holes 122, 124 are provided in the middle of the holder surface 121, 123 such that the holder surface 121, 123 forms an edge surface surrounding the through hole 122, 124. Further, the through hole 122, 124 extends form the holder surface 121, 123 to the back surface 63′ of the substrate support 60.

Accordingly, the substrate holder recesses 61, 62 are arranged receive the substrate 200 such that the upper surface of the substrate is facing towards the output face 33 of the precursor supply head 30 and the substrate is against the holder surface 121, 123.

Further, the upper surface of the substrate is preferably parallel to the support surface 63 and the output face 33. In further preferable embodiment, upper surface of the substrate 200 is preferably parallel to the support surface 63 and the output face 33 and flush with support surface 63.

In FIG. 6 the substrate support is moved to the process position with moving mechanism 64, 68, 68′. In the process position the loading support 110, 112 is below the support surface 63 of the substrate support 60 and the substrate 200 is supported on the support surface 63 or the substrate holder 61, 62.

In FIG. 7 the substrate support is moved to the loading position with moving mechanism 64, 68, 68′. In the loading position the loading support 110, 112 is protrudes through the through holes 122, 124 and the loading support 110, 112 or the support end 112 is above the support surface 63 of the substrate support 60.

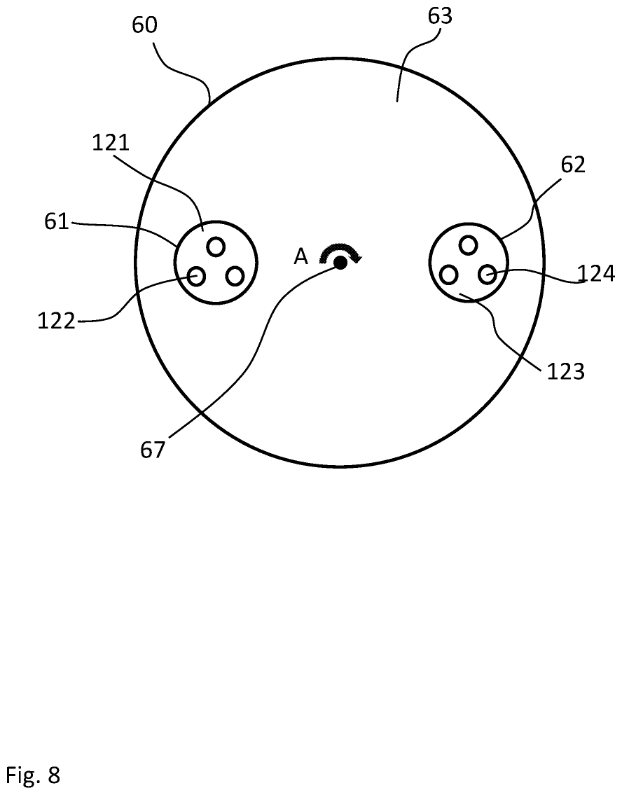

FIG. 8 shows an alternative embodiment, in which the substrate holders 61, 62 comprises three through holes 122, 124.

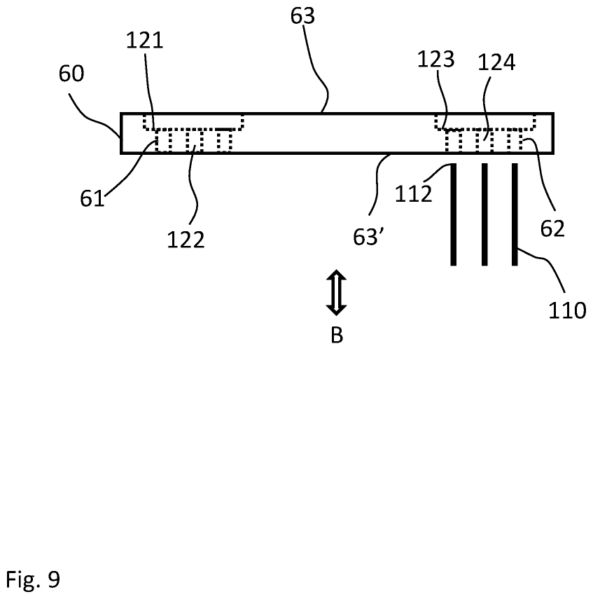

As shown in FIG. 9, the loading support 110, 112 comprises three separate loading supports 110, 112 or loading pins arranged to fit to the three through holes 122, 124 of the substrate support 60 and substrate holders 61, 62 of FIG. 8. The upper ends 112 of the loading pins 110 form the support ends on which the substrate 20 is supported.

There could also be more than three through holes 122, 124 and more than three loading supports or loading pins 110, 112.

FIG. 10 shows an alternative loading support 110, 112. The loading support comprises one support rod 110 provided with three end pins 112 to the upper end of the support rod 110. The end pins 112 are arranged to fit to the three through holes 122, 124 of the substrate support 60 and substrate holders 61, 62 of FIG. 8. The upper ends of the loading pins 112 form the support ends on which the substrate 20 is supported. The could also be more than three through holes 122, 124 and more than three loading pins 112.

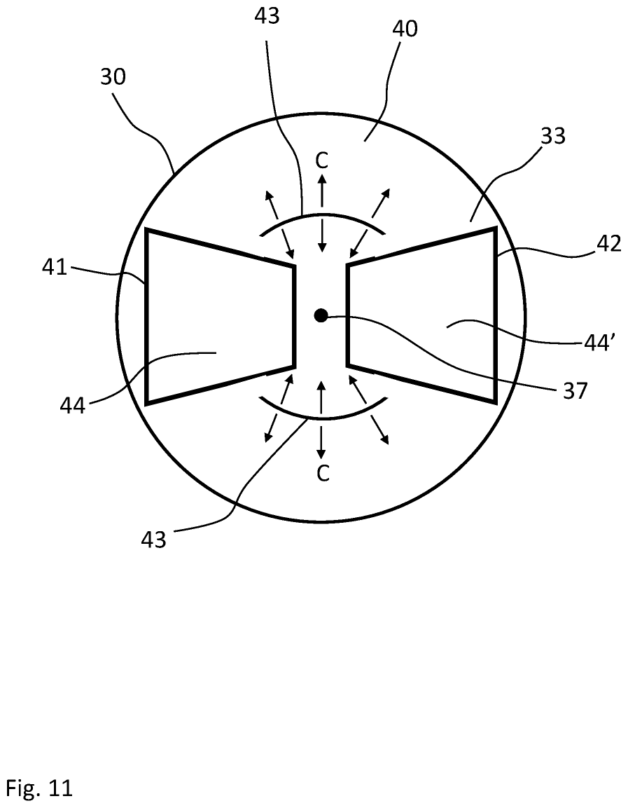

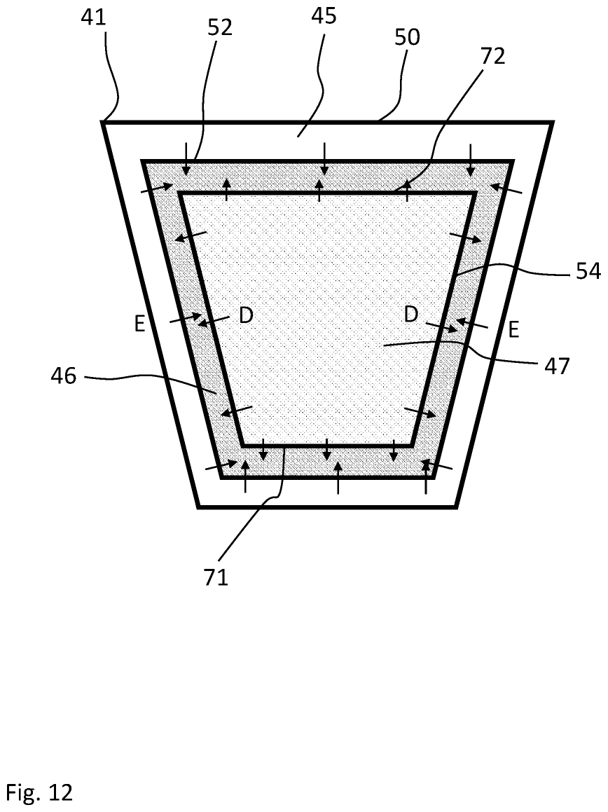

FIG. 11 shows one embodiment of the precursor supply head 30 and the output face 33 thereof. The precursor supply head 30 and the output face 33 has a head centre point 37 or head central axis 37. The head centre point 37 is the centre point of the circular output face 33.

The output face 33 is provided with two gas distribution elements 41, 42 via which precursors are supplied. The two gas distribution elements 41, 42 provide two reaction zones 44, 44′, respectively.

In one embodiment, a first gas distribution element 41 and a first reaction zone 44 is arranged to supply a first precursor. Similarly, a second gas distribution element 42 and a second reaction zone 44′ is arranged to supply a second precursor.

The first and second gas distribution elements 41, 42, and the first and second reaction zones 44, 44′, respectively, are provided symmetrically relative to each other on the output face 33. The first and second gas distribution elements 41, 42 are arranged to the output face 33 opposite to each other on opposite sides of the head centre point 37. The gas distribution elements 40, 40′ are arranged successively or adjacent to each other in the rotation direction A.

In alternative embodiments, there may be one or more gas distribution elements 41, 42. Preferably, there are two or more gas distribution elements 41, 42 arranged symmetrically relative to each other and the head centre point 37.

The precursor supply head 30 comprises intermediate purge gas feeding nozzles 43 arranged to the output face 33 adjacent the gas distribution elements 41, 42 or the reaction zones 44, 44′.

Accordingly, intermediate purge gas feeding nozzles 43 are arranged adjacent each of the gas distribution elements 41, 42 or the reaction zones 44, 44′. on opposite sides of the gas distribution elements 41, 42 or the reaction zones 44, 44′, as shown in FIG. 11. Further, intermediate purge gas feeding nozzles 43 are arranged between adjacent gas distribution elements 41, 42 or reaction zones 44, 44′. The term adjacent in connection with the intermediate purge gas nozzles 43 means adjacent the gas distribution element 41, 42 or the reaction zone 44, 44′ in the rotation direction A on the output face 33 in the rotation direction A around the head centre point 37. The term between in connection with the intermediate purge gas nozzles 43 means between two gas distribution elements 41, 42 or two reaction zones 44, 44′ in the rotation direction A on the output face 33.

In the embodiment of FIG. 11, the intermediate purge gas feeding nozzles 43 have a longitudinal curved form and are arranged to extend between the adjacent reaction zones 44, 44′. Furthermore, the intermediate purge gas feeding nozzles 43 are arranged to extend in the rotation direction A around the head centre point 37.

The purge gas flow C is directed in radial direction of the rotation direction A or in radial direction of the head centre point, as shown in FIG. 11. This provides transversal purge gas flow between the adjacent gas distribution elements 41, 42 or adjacent reaction zones 44, 44′.

The curved intermediate purge gas feeding nozzles 42 may be replaced by longitudinal linear intermediate purge gas feeding nozzles 43 extending in a direction between adjacent the adjacent gas distribution elements 41, 42 or adjacent reaction zones 44, 44′. Alternatively, the intermediate purge gas feeding nozzles 43 of FIG. 11 may be curved in alternative manner between adjacent the adjacent gas distribution elements 41, 42 or adjacent reaction zones 44, 44′.

Further alternatively, the longitudinal intermediate purge gas feeding nozzles 43 may be arranged on the output face 33 and to extend in a direction away from the head centre point 37 of the precursor supply head 30. The longitudinal intermediate purge gas feeding nozzles 43 are thus arranged to extend radially in a direction away from the head centre point 37 of the precursor supply head 30. The longitudinal intermediate purge gas feeding nozzles 43 are arranged between adjacent the adjacent gas distribution elements 41, 42 or adjacent reaction zones 44, 44′ in the rotation direction A.

FIG. 12 shows schematically one embodiment of a gas distribution element 41 or a reaction zone 44.

The gas distribution element 41 or the reaction zone 44, 44′ comprises a precursor supply zone 47 open to the output face 33 of the precursor supply head 30 for supplying precursor.

The precursor supply zone 47 of the gas distribution element 41 is provided by a precursor supply nozzle 54.

The precursor supply zone 47 is formed as a precursor supply area and arranged as a central area of the reaction zone 44 or the gas distribution element 41.

Further, the precursor supply nozzle 54 is arranged to provide a central nozzle of the gas distribution element 41.

The gas distribution element 41 or the reaction zone 44 further comprises a suction zone 46 open to the output face 33 of the precursor supply head 30. The suction zone 46 and arranged to surround the precursor supply zone 47 at the output face 33 of the precursor supply head 30.

The suction zone 46 of the gas distribution element 41 is provided by a suction nozzle 52. The suction nozzle 52 is arranged to surround the precursor supply nozzle 54 in the gas distribution element 41 and on the output surface 33.

Accordingly, the suction zone 46 is arranged to surround the precursor supply zone 47 circumferentially in the reaction zone 44 and on the output face 33.

Similarly, the suction nozzle 52 is arranged surround the precursor supply nozzle 54 circumferentially in the gas distribution element 41 and on the output surface 33.

Therefore, the suction zone 46 and the suction nozzle 52 surround the precursor supply zone 47 and the precursor supply nozzle 54, respectively, from all directions on the output face 33.

As shown in FIG. 12, precursor supplied from the precursor supply zone 47 and the precursor supply nozzle 54 flows from the precursor supply zone 47 towards the suction zone 46 as indicated by arrows D. Thus, precursor is prevented from escaping away from the reaction zone 44 and from the gas distribution element 41 to surroundings.

In preferred embodiments, the gas distribution element 41 or the reaction zone 44 further comprises a purge gas supply zone 45 open to the output face 33 of the precursor supply head 30. The purge gas supply zone 45 is arranged to surround the suction zone 46 and the precursor supply zone 47 at the output face 33 of the precursor supply head 30. Accordingly, the suction zone 46 is provided between the precursor supply zone 47 and the purge gas supply zone 45 at the output face 33 of the precursor supply head 30.

The purge gas supply zone 45 of the gas distribution element 41 is provided by a purge gas supply nozzle 50. The purge gas supply nozzle 50 is arranged to surround the suction nozzle 52 in the gas distribution element 41 and on the output surface 33.

Accordingly, the purge gas supply zone 45 is arranged to surround the suction zone 46 circumferentially in the reaction zone 44 and on the output face 33.

Similarly, the purge gas supply nozzle 50 is arranged surround the suction nozzle 52 circumferentially in the gas distribution element 41 and on the output surface 33.

Therefore, the purge gas supply zone 45 and the purge gas supply nozzle 50 surround the suction zone 466 and the suction nozzle 52, respectively, from all directions on the output face 33.

As shown in FIG. 12, purge gas supplied from the purge gas supply zone 45 and the purge gas supply nozzle 50 flows from the purge gas supply zone towards the suction zone 46 as indicated by arrows E.

The purge gas flow direction E is opposite to the precursor flow direction D. Thus, precursor is efficiently prevented from escaping away from the reaction zone 44 and from the gas distribution element 41 to surroundings.

According to the above mentioned, the suction zone 46 is provided between the precursor supply zone 47 and the purge gas supply zone 45 in the reaction zone 44 on the output face 33. Further, the suction nozzle 52 is arranged between the precursor supply nozzle 54 and the purge gas supply nozzle 50 in the gas distribution element 41 on the output face 33.

The invention has been described above with reference to the examples shown in the figures. However, the invention is in no way restricted to the above examples but may vary within the scope of the claims.

1.-16. (canceled)

17. An atomic layer deposition apparatus for processing a surface of a substrate successively with at least a first precursor and a second precursor, the apparatus comprising:
a substrate support having a support surface and arranged to support one or more substrates;
a precursor supply head having an output face via which precursors are supplied;
the support surface of the substrate support and the output face of the precursor supply head being arranged opposite to each other such that a reaction gap is provided between the support surface of the substrate support and the output face of the precursor supply head; and
a moving mechanism, the substrate support and the precursor supply head are arranged to be rotated relative to each other with the moving mechanism such that the support surface of the substrate support and the output face of the precursor supply head are arranged to be rotated relative to each other,
wherein the moving mechanism is further arranged to move the substrate support and the precursor supply head relative to each other in a moving direction extending between the support surface of the substrate support and the output face of the precursor supply head such that the reaction gap is adjusted.

18. The apparatus according to claim 17, wherein:
the moving mechanism is arranged to move the substrate support for moving the substrate support and the precursor supply head relative to each other in the moving direction between the support surface of the substrate support and the output face of the precursor supply head; or
the moving mechanism is arranged to move the precursor supply head for moving the substrate support and the precursor supply head relative to each other in the moving direction between the support surface of the substrate support and the output face of the precursor supply head.

19. The apparatus according to claim 17, wherein:
the moving mechanism is arranged to rotate the substrate support for rotating the support surface of the substrate support and the output face of the precursor supply head are arranged to be rotated relative to each other; or
the moving mechanism is arranged to rotate the precursor supply head for rotating the support surface of the substrate support and the output face of the precursor supply head are arranged to be rotated relative to each other.

20. The apparatus according to claim 17, wherein:
the output face of the precursor supply head and the support surface of the substrate support are arranged parallel to each other such that a uniform reaction gap is provided between the support surface of the substrate support and the output face of the precursor supply head; and
the moving mechanism is arranged to move the substrate support and the precursor supply head relative to each other in the moving direction extending perpendicularly to the support surface of the substrate support.

21. The apparatus according to claim 17, wherein:
the moving mechanism comprises a rotating axis around which the substrate support and the precursor supply head are arranged to be rotated relative to each other; and
the rotating axis is arranged perpendicularly to the support surface, or the rotating axis is arranged parallel to the moving direction.

22. The apparatus according to claim 17, wherein:
the moving mechanism comprises a rotating mechanism arranged to rotate the substrate support and the precursor supply head relative to each; and
the moving mechanism comprises a transfer mechanism arranged to move the substrate support and the precursor supply head relative to each other in the moving direction; or
the moving mechanism comprises a rotating mechanism arranged to rotate the substrate support; and
the moving mechanism comprises a transfer mechanism arranged to move the substrate support in the moving direction.

23. The apparatus according to claim 17, wherein:
the moving mechanism is arranged to move the substrate support in the moving direction,
the substrate support comprises a back surface opposite the support surface, and the substrate support further comprises one or more through holes extending through the substrate support between the back surface and the support surface in the moving direction, and
the apparatus further comprises a loading support extending in the moving direction, the loading support being arranged to fit through the one or more through holes upon moving the substrate support with the moving mechanism in the moving direction and relative to the loading support.

24. The apparatus according to claim 23, wherein:
the moving mechanism is arranged to move the substrate support in the moving direction to a process position in which the loading support is below the support surface of the substrate support, and
the moving mechanism is arranged to move the substrate support in the moving direction to a loading position in which the loading support is above the support surface of the substrate support.

25. The apparatus according to claim 17, wherein:
the apparatus further comprises a loading device arranged to load and unload substrates to the reaction gap between the support surface of the substrate support and the output face of the precursor supply head; or
the apparatus further comprises a loading device arranged to load and unload substrates to the reaction gap between the support surface of the substrate support and the output face of the precursor supply head in a loading direction, the loading direction being transverse or perpendicular to the moving direction.

26. A method for operating an atomic layer deposition apparatus, the apparatus comprising:
a substrate support having a support surface and arranged to support one or more substrates;
a precursor supply head having an output face via which precursors are supplied; and
the support surface of the substrate support and the output face of the precursor supply head being arranged opposite to each other such that a reaction gap is provided between the support surface of the substrate support and the output face of the precursor supply head, the method comprising:
rotating the substrate support and the precursor supply head relative to each other with the moving mechanism during processing the one or more substrates such that the support surface of the substrate support and the output face of the precursor supply head are arranged to be rotated relative to each other, and
moving the substrate support and the precursor supply head relative to each other in a moving direction extending between the support surface of the substrate support and the output face of the precursor supply head such that the reaction gap is adjusted for adjusting reaction gap.

27. The method according to claim 26, wherein:
moving the substrate support relative to the precursor supply head in the moving direction for adjusting reaction gap; or
moving the precursor supply head relative to the substrate support in the moving direction for adjusting reaction gap.

28. The method according to claim 26, wherein the output face of the precursor supply head and the support surface of the substrate support are arranged parallel to each other such that a uniform reaction gap is provided between the support surface of the substrate support and the output face of the precursor supply head, and the method comprises moving the substrate support and the precursor supply head relative to each other in the moving direction extending perpendicularly to the support surface of the substrate support.

29. The method according to claim 26, wherein the method comprises moving the substrate support in the moving direction to a process position in which the reaction gap has a first gap height, and moving the substrate support in the moving direction to a loading position in which the reaction gap has a second gap height, the second gap height being greater than the first gap height.

30. The method according to claim 29, wherein the method comprises:
moving the substrate support in the moving direction to the loading position;
loading one or more substrates to the reaction gap in a loading direction, the loading direction being transverse or perpendicular to the moving direction; and
moving the substrate support in the moving direction to the process position; or
moving the substrate support in the moving direction to the loading position;
loading one or more substrates to the reaction gap in a loading direction, the loading direction being transverse or perpendicular to the moving direction;
moving the substrate support in the moving direction to the process position;
processing the one or more substrates by supplying precursors to the reaction gap via the output face of the precursor supply head;
moving the substrate support in the moving direction to the loading position; and
unloading the one or more substrates from the reaction gap in the loading direction.

31. The method according to claim 29, wherein:
the substrate support comprises a back surface opposite the support surface, and the substrate support further comprises one or more through holes extending through the substrate support between the back surface and the support surface in the moving direction; and
the apparatus further comprises a loading support extending in the moving direction, the loading support being arranged to fit through the one or more through holes upon moving the substrate support with the moving mechanism in the moving direction and relative to the loading support,
the method comprises:
moving the substrate support in the moving direction to the loading position in which the reaction gap has the second height and in which the loading support extends through the one or more through holes above the support surface of the substrate support, and
moving the substrate support in the moving direction to the process position in which the reaction gap has the first height and in which the loading support is below the support surface of the substrate support; or
moving the substrate support in the moving direction to the loading position in which the reaction gap has the second height and in which the loading support extends through the one or more through holes above the support surface of the substrate support,
loading a substrate on the loading support in the loading direction, and
moving the substrate support in the moving direction to the process position in which the reaction gap has the first height and in which the loading support is below the support surface of the substrate support such that the substrate is placed on the support surface of the substrate support during the moving of the substrate support from the loading position to the process position; or
moving the substrate support in the moving direction to the loading position in which the reaction gap has the second height and in which the loading support extends through the one or more through holes above the support surface of the substrate support,
loading a substrate on the loading support in the loading direction,
moving the substrate support in the moving direction to the process position in which the reaction gap has the first height and in which the loading support is below the support surface of the substrate support such that the substrate is placed on the support surface of the substrate support during the moving of the substrate support from the loading position to the process position,
processing the one or more substrates by supplying precursors to the reaction gap via the output face of the precursor supply head, and
moving the substrate support in the moving direction to the loading position in which the reaction gap has the second height and in which the loading support extends through the one or more through holes above the support surface of the substrate support such that the substrate is placed on the loading support during the moving of the substrate support from the process position to the loading position.

32. The method according to claim 26, wherein the method is carried out with an atomic layer deposition apparatus for processing a surface of a substrate successively with at least a first precursor and a second precursor, the apparatus comprising:
a substrate support having a support surface and arranged to support one or more substrates;
a precursor supply head having an output face via which precursors are supplied;
the support surface of the substrate support and the output face of the precursor supply head being arranged opposite to each other such that a reaction gap is provided between the support surface of the substrate support and the output face of the precursor supply head; and
a moving mechanism, the substrate support and the precursor supply head are arranged to be rotated relative to each other with the moving mechanism such that the support surface of the substrate support and the output face of the precursor supply head are arranged to be rotated relative to each other,
wherein the moving mechanism is further arranged to move the substrate support and the precursor supply head relative to each other in a moving direction extending between the support surface of the substrate support and the output face of the precursor supply head such that the reaction gap is adjusted.
